(19) United States
(12) Patent Application Publication
(10) Pub. No.: US 2025/0393135 A1
(43) Pub. Date: Dec. 25, 2025

(54) CARD EDGE TYPE PRINTED WIRING BOARD

(71) Applicant: Nippon Tanshi Co., Ltd., Hiratsuka-shi, Kanagawa (JP)

(72) Inventors: Shinya ENOMOTO, Kanagawa (JP); Osamu NISHIMURA, Kanagawa (JP); Koichi ITO, Kyoto (JP); Daisuke SABURI, Kyoto (JP)

(21) Appl. No.: 18/708,035

(22) PCT Filed: Jul. 13, 2022
(86) PCT No.: PCT/JP2022/027556

§ 371 Date: Sep. 8, 2025

(30) Foreign Application Priority Data
Nov. 8, 2021 (JP) 2021-181750

(51) Int. Cl. H05K 3/28; H05K 1/11

(52) U.S. Cl. CPC H05K 3/28; H05K 1/117; H05K 2201/0989; H05K 2203/1377

(57) ABSTRACT

In a card edge type printed wiring board including a terminal portion provided to reach a vicinity of an edge of a base layer, an abrasion resistance layer made of metal is provided on a portion of an electric insulation layer between a board edge and an end portion of the terminal portion on a side of the board edge, and the abrasion resistance layer is spaced at an interval from the end portion of the terminal portion.

### TECHNICAL FIELD

The present invention relates to a card edge type printed wiring board, and more particularly, to a card edge type printed wiring board based on a metal plate.

### BACKGROUND ART

A known printed wiring board based on a metal plate includes a base layer made of metal such as aluminum, an electric insulation layer made of resin and the like and laminated on one surface of the base layer, and a conductive pattern made of copper foil and the like and formed on the electric insulation layer (for example, Patent Documents 1and 2).

The base layer made of metal has better heat dissipation than a base layer made of resin, but has a relatively large coefficient of linear expansion, and repeated thermal expansion and contraction of the base layer made of metal applies stress to soldering portions and the like thereof. Accordingly, it is necessary to make the electric insulation layer soft to alleviate stress caused by the thermal expansion and contraction.

In a case where the printed wiring board based on a metal plate is applied to a card edge type printed wiring board, the conductive pattern includes a terminal portion provided to reach the vicinity of an edge of a board (the base layer and the electric insulation layer) such that a connector terminal to be connected can contact conductively with the terminal portion.

### PRIOR ART DOCUMENT(S)

### Patent Document(s)

Patent Document 1: JP2011-507235A

Patent Document 2: JP2018-81985A

### SUMMARY OF THE INVENTION

### Task to be Accomplished by the Invention

If the terminal portion is provided to reach the edge of the board, the clearance between an end portion of the terminal portion on a side of the edge of the board and an end surface of the base layer exposed to the edge of the board is set to a short distance corresponding to the thickness of the electric insulation layer, and therefore insulation breakdown due to creeping discharge is likely to occur between the terminal portion and the base layer. To avoid this insulation breakdown, the terminal portion may terminate in the vicinity of the edge (before the edge) of the board so that a larger clearance can be set between the end portion of the terminal portion on the side of the edge of the board and the end surface of the base layer.

In a case where the terminal portion terminates in the vicinity of the edge of the board, the electric insulation layer may be exposed between the edge of the board and the end portion of the terminal portion on the side of the edge of the board. Accordingly, when the connector terminal moves from the edge of the board to the terminal portion at the installation of a connector or when the connector terminal moves from the terminal portion to the edge of the board at the removal of the connector, the connector terminal comes into sliding contact with the electric insulation layer between the edge of the board and the end portion of the terminal portion on the side of the edge of the board, and the electric insulation layer is scraped accordingly. This tendency becomes noticeable in a board having a soft electric insulation layer.

If the electric insulation layer is scraped, the base layer is exposed to the outside, and an insulation failure may occur accordingly. Additionally, shavings of the electric insulation layer may enter a space between the terminal portion and the connector terminal, which may cause the conduction failure between the terminal portion and the connector terminal.

In view of the above background, an object of the present invention is, in a card edge type printed wiring board based on a metal plate, to prevent an electric insulation layer between an edge of a board and a terminal portion of a conductive pattern with which a connector terminal contacts conductively from being scraped by the sliding contact with the connector terminal, and inhibit the occurrence of insulation failure and conduction failure.

### Means to Accomplish the Task

To achieve such an object, one aspect of the present invention provides a card edge type printed wiring board (10), comprising: a base layer (20) made of metal; an electric insulation layer (22) laminated on one surface of the base layer; and a conductive pattern (24) formed on the electric insulation layer, wherein the conductive pattern includes a terminal portion (26) provided to reach a vicinity of an edge (20A) of the base layer such that a connector terminal (52) can contact conductively with the terminal portion, and an abrasion resistance layer (28) made of metal is provided on a portion of the electric insulation layer between an end portion (26A) of the terminal portion on a side of the edge and the edge of the base layer, and the abrasion resistance layer is spaced at an interval (G2) from the end portion of the terminal portion.

According to this aspect, the abrasion resistance layer prevents the electric insulation layer between an edge of a board and the end portion of the terminal portion on a side of the edge of the board from being scraped by the sliding contact with the connector terminal, thereby inhibiting the occurrence of insulation failure and conduction failure.

In the above aspect, preferably, the abrasion resistance layer extends to reach the edge.

According to this aspect, it is possible to reliably prevent the electric insulation layer from being scraped by the sliding contact with the connector terminal in a portion of the electric insulation layer on the side of the edge.

In the above aspect, preferably, the abrasion resistance layer terminates to be spaced at an interval from the edge of the base layer.

According to this aspect, it is possible to improve the electric insulation properties between the base layer and the abrasion resistance layer.

In the above aspect, preferably, the abrasion resistance layer is made of the same conductive material as the terminal portion, and has substantially the same thickness as the terminal portion.

According to this aspect, a separate process for forming the abrasion resistance layer is not necessary, and a top surface of the terminal portion and a top surface of the abrasion resistance layer are provided flush with each other.

In the above aspect, preferably, the terminal portion comprises a plurality of terminal portions aligned in a lateral direction, and the abrasion resistance layer is formed into a strip extending in the lateral direction, and is provided commonly to the plurality of terminal portions.

According to this aspect, the abrasion resistance layer is unlikely to separate from the electric insulation layer.

In the above aspect, preferably, the card edge type printed wiring board further comprises a protection layer having electric insulation properties and covering the abrasion resistance layer.

According to this aspect, it is possible to improve the electric insulation properties of the abrasion resistance layer.

In the above aspect, preferably, the protection layer includes a portion that covers a portion of the terminal portion in a vicinity of the end portion.

According to this aspect, it is possible to reliably protect the electric insulation layer since no gap is formed between the end portion of the terminal portion and the protection layer.

In the above aspect, preferably, the protection layer includes a portion covering an end surface of the abrasion resistance layer on the side of the edge of the base layer.

According to this aspect, it is possible to improve the electric insulation properties of the abrasion resistance layer relative to the base layer.

To achieve such an object, one aspect of the present invention provides a card edge type printed wiring board, comprising: a base layer made of metal; an electric insulation layer laminated on one surface of the base layer; and a conductive pattern formed on the electric insulation layer, wherein the conductive pattern includes a terminal portion provided to reach a vicinity of an edge of the base layer such that a connector terminal can contact conductively with the terminal portion, and a protection layer having electric insulation properties is provided at least on a portion of the electric insulation layer between an end portion of the terminal portion on a side of the edge and the edge of the base layer.

According to this aspect, the protection layer prevents the electric insulation layer between an edge of a board and the end portion of the terminal portion on a side of the edge of the board from being scraped by the sliding contact with the connector terminal, thereby inhibiting the occurrence of insulation failure and conduction failure.

In the above aspect, preferably, the card edge type printed wiring board according to claim 9, wherein the protection layer includes a portion that covers a portion of the terminal portion in a vicinity of the end portion.

According to this aspect, it is possible to reliably protect the electric insulation layer since no gap is formed between the end portion of the terminal portion and the protection layer.

### Effect of the Invention

Thus, according to the above aspects, it is possible to prevent an electric insulation layer between an edge of a board and an end portion of a terminal portion of a conductive pattern on a side of the edge of the board with which a connector terminal contacts conductively from being scraped by the sliding contact with the connector terminal, and inhibit the occurrence of insulation failure and conduction failure.

### BRIEF DESCRIPTION OF THE DRAWINGS

FIG. 1 is a perspective view showing an outline of a card edge type printed wiring board and a connector connected thereto according to the present invention;

FIG. 2 is an enlarged bottom view of a main portion of the card edge type printed wiring board according to Embodiment 1;

FIG. 3 is a cross-sectional view taken along a line III-III in FIG. 2;

FIG. 4 is an enlarged bottom view of a main portion of a card edge type printed wiring board according to Embodiment 2;

FIG. 5 is a cross-sectional view taken along a line V-V in FIG. 4;

FIG. 6 is an enlarged bottom view of a main portion of a card edge type printed wiring board according to Embodiment 3;

FIG. 7 is an enlarged bottom view of a main portion of a card edge type printed wiring board according to Embodiment 4;

FIG. 8 is a cross-sectional view taken along a line VIII-VIII of FIG. 7;

FIG. 9 is a cross-sectional view of a main portion of a card edge type printed wiring board according to Embodiment 5; and

FIG. 10 is an enlarged bottom view of a main portion of a card edge type printed wiring board according to Embodiment 6.

### MODE(S) FOR CARRYING OUT THE INVENTION

Hereinafter, embodiments of a card edge type printed wiring board according to the present invention will be described with reference to the drawings.

### Embodiment 1

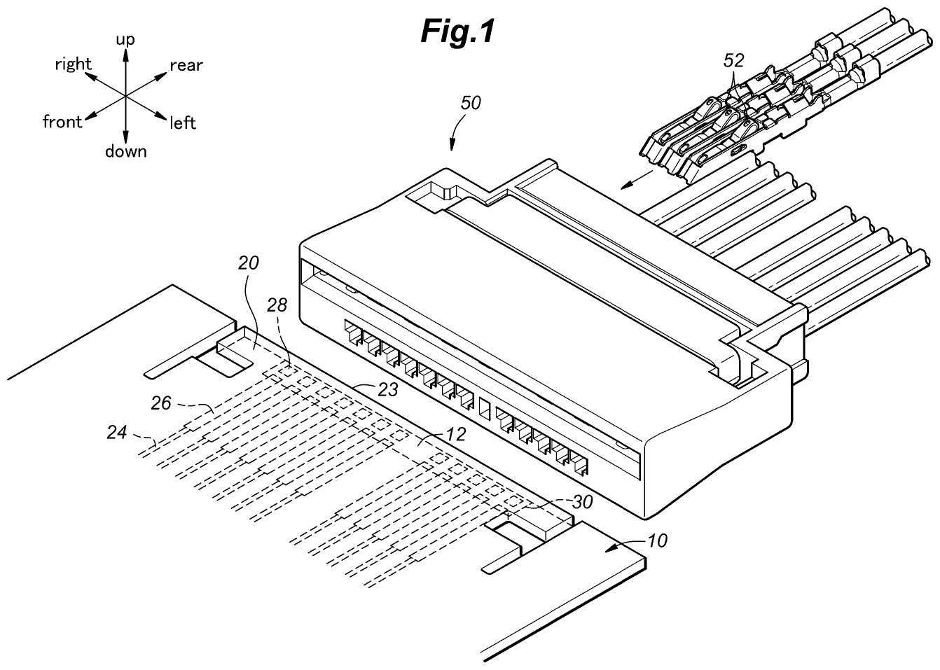

Embodiment 1 of the card edge type printed wiring board and a card edge connector connected thereto will be described with reference to FIGS. 1 to 3.

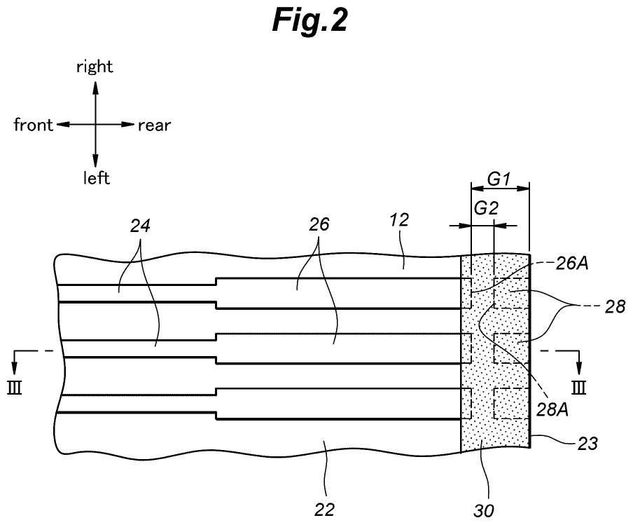

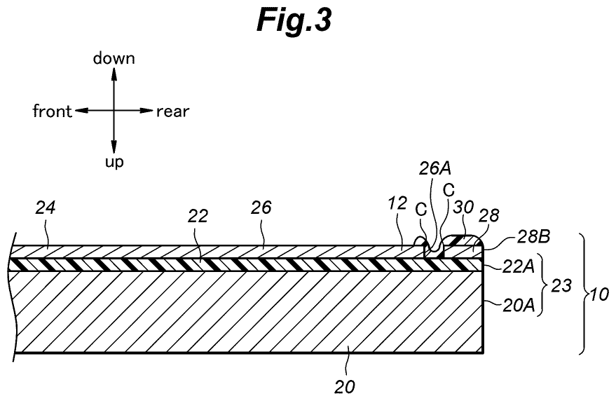

FIG. 1 shows a card edge type printed wiring board 10 (hereinafter abbreviated as “the wiring board 10”) and a card edge connector 50 (hereinafter abbreviated as “the connector 50”) removably attached to an edge portion 12 of the wiring board 10. FIG. 2 shows an enlarged bottom view of a main portion of the wiring board 10 seen from below. FIG. 3 is a cross-sectional view taken along a line III-III in FIG. 2.

As shown in FIG. 3, the wiring board 10 includes a base layer 20, an electric insulation layer 22 laminated on one surface of the base layer 20, and a conductive pattern 24 formed on the electric insulation layer 22.

The base layer 20 is made of metal such as an aluminum plate, a copper plate, an iron-based metal plate, and the like having a required thickness. The base layer 20 preferably has a thickness of substantially 1 to 2 mm.

The electric insulation layer 22 is laminated on the entire area of the one surface of the base layer 20, and a circumferential edge of the electric insulation layer 22 reaches an edge 20A of the base layer 20 on a side of the edge portion 12. Accordingly, the edge 20A of the base layer 20 and an edge 22A of the electric insulation layer 22 on the side of the edge portion 12 are provided substantially flush with each other. The edge 20A of the base layer 20 and the edge 22A of the electric insulation layer 22 on the side of the edge portion 12 will be collectively referred to as “the board edge 23”. The electric insulation layer 22 is made of resin such as polyimide or epoxy having electric insulation properties, and preferably has a uniform layer thickness of substantially 100 μm. The electric insulation layer 22 has hardness that a storage elastic modulus thereof is substantially 1 GPa or less, and preferably has hardness that the storage elastic modulus thereof is 0.3 GPa or less.

The conductive pattern 24 is made of copper foil and the like formed into a prescribed wiring pattern by etching. The conductive pattern 24 includes a plurality of terminal portions 26 with which connector terminals 52 of the connector 50 can contact conductively. Each terminal portion 26 has a rectangular shape elongated in the front-and-rear direction (an attachment/removal direction to/from the edge portion 12) in a plan view. The terminal portions 26 are aligned at prescribed intervals in the lateral direction.

Each terminal portion 26 reaches the vicinity of the board edge 23 in the edge portion 12. An interval G1 (see FIG. 2) in the front-and-rear direction is formed on the electric insulation layer 22 between an end portion 26A of each terminal portion 26 on a side of the board edge 23 and the board edge 23. The clearance (interval G1) between the end portion 26A of each terminal portion 26 and the board edge 23 is variable within the range that the insulation between the conductive pattern 24 and the base layer 20 made of metal can be appropriately secured and the conductive contact between each terminal portion 26 and the connector terminal 52 can be appropriately secured.

Abrasion resistance layers 28 made of metal are provided on the electric insulation layer 22 between the end portions 26A of the respective terminal portions 26 and the board edge 23. Each abrasion resistance layer 28 is spaced at an interval G2 from the end portion 26A of the corresponding terminal portion 26. Each abrasion resistance layer 28 has a rectangular shape extending in the front-and-rear direction from an edge 28A on a side of the end portion 26A of the terminal portion 26 to the board edge 23. Accordingly, the edge 28B of the abrasion resistance layer 28 on the side of the board edge 23 and the board edge 23 are provided substantially flush with each other.

The interval G2 is formed between the edge 28A of the abrasion resistance layer 28 and the end portion 26A of the terminal portion 26, and defines an insulating gap for electrically separating the terminal portion 26 and the abrasion resistance layer 28. The interval G2 is determined according to the specifications of the withstand voltage, and may preferably be substantially 0.2 to 0.5 mm. The abrasion resistance layer 28 is also electrically separated from the base layer 20 which is grounded.

The abrasion resistance layer 28 is made of the same conductive material as the conductive pattern 24. The abrasion resistance layer 28 is formed together with the conductive pattern 24 by etching copper foil and the like laminated on the base layer 20. Accordingly, a separate process for forming the abrasion resistance layer 28 is not necessary. Further, the abrasion resistance layer 28 has substantially the same thickness as the conductive pattern 24. Accordingly, a top surface of the terminal portion 26 and a top surface of the abrasion resistance layer 28 are provided flush with each other, so that the connector terminal 52 can slide smoothly from the abrasion resistance layer 28 to the terminal portion 26.

The wiring board 10 further includes a protection layer 30 having electric insulation properties. The protection layer 30 continuously covers the abrasion resistance layer 28, a portion of the electric insulation layer 22 exposed to the outside at the interval G2, and a portion of each terminal portion 26 in the vicinity of the end portion 26A. The protection layer 30 is made of resin solder resist and the like. As shown in FIG. 2, the protection layer 30 is provided commonly to the plurality of terminal portions 26, and is formed into a strip extending in an alignment direction (lateral direction) of the terminal portions 26. Preferably, the protection layer 30 is made of a material having higher hardness and better wear resistance and cutting resistance than the electric insulation layer 22.

As shown in FIG. 3, portions of the protection layer 30 that correspond to edge corner portions C (corner portions) of the terminal portion 26 and the abrasion resistance layer 28 tend to be thinner due to a layering process (coating process). The portions of the protection layer 30 that start from the edge corner portions C and where the layer thickness is the thinnest may have a layer thickness of substantially 5 μm or more.

The protection layer 30 includes a portion covering a side of the end portion 26A of the terminal portion 26 and overlapping with the side of the end portion 26A of the terminal portion 26. Accordingly, it is possible to reliably prevent the electric insulation layer 22 from being exposed to the outside at the interval G2. That is, the interval G2 between each abrasion resistance layer 28 and the corresponding end portion 26A of the terminal portion 26 is reliably filled with the protection layer 30. Further, the protection layer 30 includes a portion that overlaps with the terminal portion 26. Accordingly, the protection layer 30 inhibits the end portion 26A of the terminal portion 26 from being removed from the electric insulation layer 22. If the protection layer 30 covers the entire terminal portion 26, the conductive connection between the terminal portion 26 and the connector terminal 52 is blocked. Accordingly, the protection layer 30 covers only a portion of the terminal portion 26 in the vicinity of the end portion 26A.

When the connector 50 is attached to or removed from the wiring board 10, the connector terminal 52 does not come into sliding contact with the electric insulation layer 22 due to the presence of the abrasion resistance layer 28 and the protection layer 30.

Accordingly, it is possible to prevent the electric insulation layer 22 between the end portion 26A of each terminal portion 26 and the board edge 23 from being scraped by the sliding contact with the connector terminal 52. Accordingly, it is possible to inhibit the occurrence of insulation failure caused by scraping of the electric insulation layer 22, and to inhibit the occurrence of conduction failure caused by shavings of the electric insulation layer 22.

The abrasion resistance layer 28 mechanically protects the electric insulation layer 22 to prevent the electric insulation layer 22 from receiving mechanical damage such as abrasion. The protection layer 30 provides double mechanical protection for the electric insulation layer 22 together with the abrasion resistance layer 28. The protection layer 30 prevents the electric insulation layer 22, especially a portion of the electric insulation layer 22 exposed to the outside at the interval G2, from receiving mechanical damage due to the sliding contact with the connector terminal 52.

The protection layer 30 further functions as an electrical protection layer that prevents an electrical short circuit between the abrasion resistance layer 28 and other portions such as the base layer 20.

### Embodiment 2

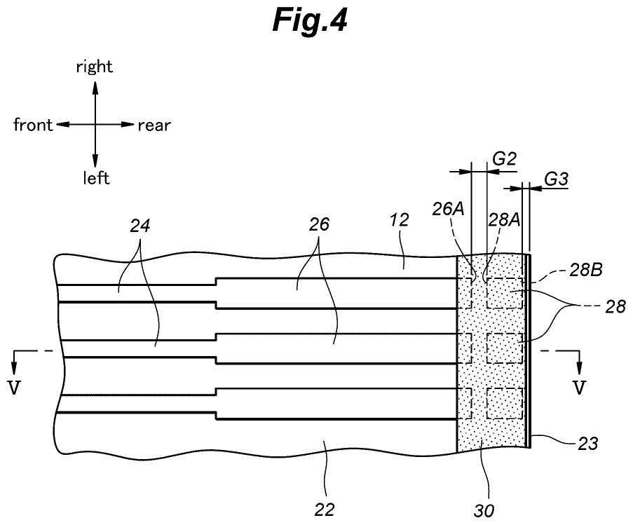

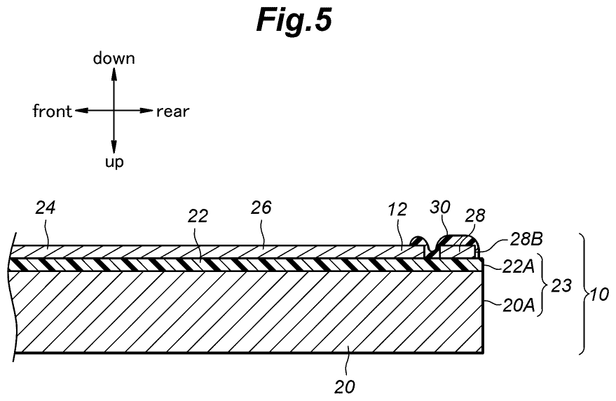

Embodiment 2 of the card edge type printed wiring board will be described with reference to FIGS. 4 and 5. In FIGS. 4 and 5, portions corresponding to those in FIGS. 2 and 3 are designated by the same reference numerals as those in FIGS. 2 and 3, and the explanation thereof will be omitted.

In Embodiment 2, each abrasion resistance layer 28, which extends between the end portion 26A of each terminal portion 26 and the board edge 23, terminates to be spaced at an interval G3 in the front-and-rear direction from the board edge 23. The protection layer 30 includes a portion that covers the edge 28B (end surface) of the abrasion resistance layer 28 on the side of the board edge 23 in addition to a portion that covers the abrasion resistance layer 28 and a portion of the electric insulation layer 22 exposed to the outside at interval G2 and a portion that covers a portion of the terminal portion 26 in the vicinity of the end portion 26A.

In Embodiment 2, the interval G3 is formed, and the protection layer 30 includes a portion that covers the edge 28B of the abrasion resistance layer 28 on the side of the board edge 23. Accordingly, it is possible to electrically separate the abrasion resistance layer 28 from the base layer 20 more reliably.

### Embodiment 3

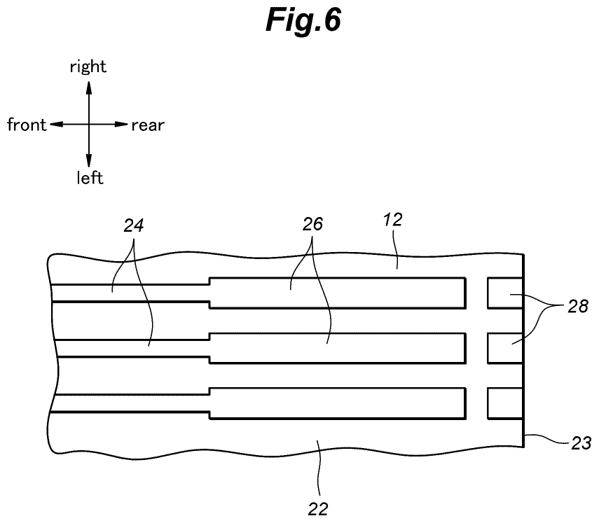

Embodiment 3 of the card edge type printed wiring board will be described with reference to FIG. 6. In FIG. 6, portions corresponding to those in FIG. 2 are designated by the same reference numerals as those in FIG. 2, and the explanation thereof will be omitted.

In Embodiment 3, the protection layer 30 is omitted. In Embodiment 3, the abrasion resistance layers 28 equivalent to the abrasion resistance layers 28 of Embodiment 1 are provided. Accordingly, it is possible to prevent the electric insulation layer 22 between the end portion 26A of each terminal portion 26 and the board edge 23 from being scraped by the sliding contact with the connector terminal 52. Accordingly, in Embodiment 3, it is possible to inhibit the occurrence of insulation failure caused by scraping of the electric insulation layer 22, and to inhibit the occurrence of conduction failure caused by shavings of the electric insulation layer 22.

### Embodiment 4

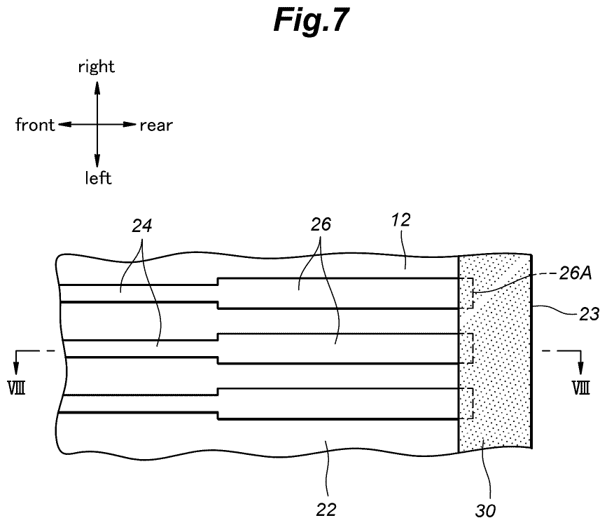

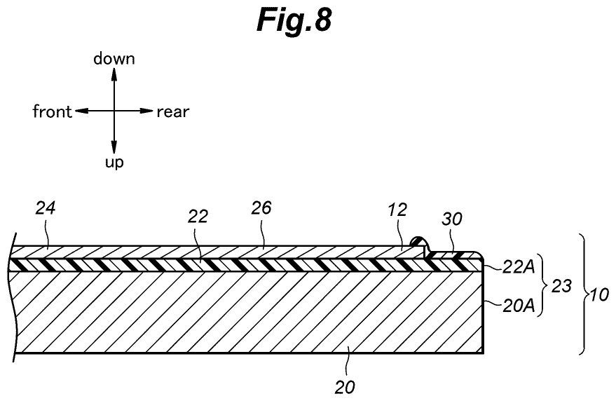

Embodiment 4 of the card edge type printed wiring board will be described with reference to FIGS. 7 and 8. In FIGS. 7 and 8, portions corresponding to those in FIGS. 2 and 3 are designated by the same reference numerals as those in FIGS. 2 and 3, and the explanation thereof will be omitted.

In Embodiment 4, the abrasion resistance layer 28 is omitted. In Embodiment 4, the protection layer 30 equivalent to the protection layer 30 of Embodiment 1 is provided. The protection layer 30 extends continuously from the board edge 23 to a portion that covers a portion of the terminal portion 26 in the vicinity of the end portion 26A.

The protection layer 30 prevents the electric insulation layer 22 between the end portion 26A of each terminal portion 26 and the board edge 23 from being scraped by the sliding contact with the connector terminal 52. Accordingly, in Embodiment 4, it is possible to inhibit the occurrence of insulation failure caused by scraping of the electric insulation layer 22, and to inhibit the occurrence of conduction failure caused by shavings of the electric insulation layer 22.

### Embodiment 5

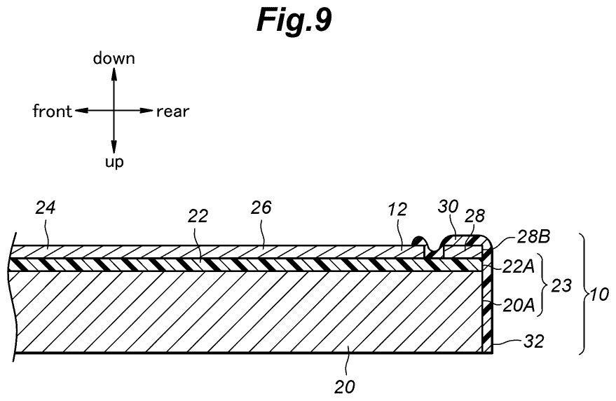

Embodiment 5 of the card edge type printed wiring board will be described with reference to FIG. 9. In FIG. 9, portions corresponding to those in FIG. 3 are designated by the same reference numerals as those in FIG. 3, and the explanation thereof will be omitted.

In Embodiment 5, the protection layer 30 includes an extension portion 32 in addition to a portion that covers the abrasion resistance layer 28 and the whole portion of the electric insulation layer 22 exposed to the outside at the interval G2 and a portion that covers a portion of the terminal portion 26 in the vicinity of the end portion 26A. The extension portion 32 continuously covers an end surface of the edge 28B of the abrasion resistance layer 28 on the side of the board edge 23, an end surface of the edge 22A of the electric insulation layer 22 on the side of the board edge 23, and the end surface of the edge 20A of the base layer 20 on the side of the board edge 23.

In Embodiment 5, the extension portion 32 improves electrical insulation properties between the base layer 20 and the abrasion resistance layer 28. Accordingly, it is possible to more reliably prevent the abrasion resistance layer 28 from being electrically connected to the base layer 20.

### Embodiment 6

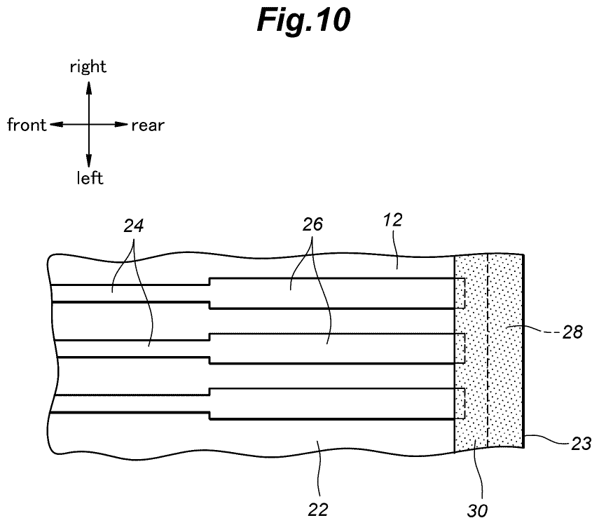

Embodiment 6 of the card edge type printed wiring board will be described with reference to FIG. 10. In FIG. 10, portions corresponding to those in FIG. 2 are designated by the same reference numerals as those in FIG. 2, and the description thereof will be omitted.

In Embodiment 6, the abrasion resistance layer 28 is formed into a strip extending in the alignment direction (lateral direction) of the plurality of terminal portions 26, and is provided commonly to the plurality of terminal portions 26.

In Embodiment 6, it is possible to prevent the electric insulation layer 22 between the end portion 26A of each terminal portion 26 and the board edge 23 from being scraped by the sliding contact with the connector terminal 52. Accordingly, in Embodiment 6, it is possible to inhibit the occurrence of insulation failure caused by scraping of the electric insulation layer 22, and to inhibit the occurrence of conduction failure caused by shavings of the electric insulation layer 22. The abrasion resistance layer 28 is not provided individually for each of the plurality of terminal portions 26. Accordingly, the abrasion resistance layer 28 is unlikely to be removed from the electric insulation layer 22 as compared with a case where the abrasion resistance layer 28 is provided individually for each of the plurality of terminal portions 26.

In the foregoing, the present invention has been described with respect to the preferred embodiments thereof. However, the present invention is not limited by such embodiments, and can be modified as appropriate without deviating from the spirit of the present invention such that those skilled in the art can easily understand the modification. The wiring board 10 may be a double-sided wiring board having the electric insulation layer 22 and the conductive pattern 24 on both sides of the base layer 20.

### GLOSSARY OF TERMS

10: card edge type printed wiring board (wiring board)
12: edge portion
20: base layer
20A: edge
22: electric insulation layer
22A: edge
23: board edge
24: conductive pattern
26: terminal portion
26A: end portion
28: abrasion resistance layer
28A: edge
28B: edge
30: protection layer
32: extension portion
50: card edge connector (connector)
52: connector terminal

1. A card edge type printed wiring board, comprising:
a base layer made of metal;
an electric insulation layer laminated on one surface of the base layer; and
a conductive pattern formed on the electric insulation layer,
wherein the conductive pattern includes a terminal portion made of a conductive material is provided to reach a vicinity of an edge of the base layer such that a connector terminal can contact conductively with the terminal portion, and
an abrasion resistance layer made of metal is provided on a portion of the electric insulation layer between an end portion of the terminal portion on a side of the edge and the edge of the base layer, and the abrasion resistance layer is spaced at an interval from the end portion of the terminal portion.

2. The card edge type printed wiring board according to claim 1, wherein the abrasion resistance layer extends to reach the edge.

3. The card edge type printed wiring board according to claim 1, wherein the abrasion resistance layer terminates to be spaced at an interval from the edge of the base layer.

4. The card edge type printed wiring board according to claim 1, wherein the abrasion resistance layer is made of the same conductive material as the terminal portion, and has substantially the same thickness as the terminal portion.

5. The card edge type printed wiring board according to claim 1, wherein the terminal portion comprises a plurality of terminal portions aligned in a lateral direction, and
the abrasion resistance layer is formed into a strip extending in the lateral direction, and is provided commonly to the plurality of terminal portions.

6. The card edge type printed wiring board according to claim 1, further comprising a protection layer having electric insulation properties and covering the abrasion resistance layer.

7. The card edge type printed wiring board according to claim 6, wherein the protection layer includes a portion that covers a portion of the terminal portion in a vicinity of the end portion.

8. The card edge type printed wiring board according to claim 6, wherein the protection layer includes a portion covering an end surface of the abrasion resistance layer on the side of the edge of the base layer.

9. A card edge type printed wiring board, comprising:
a base layer made of metal;
an electric insulation layer laminated on one surface of the base layer; and
a conductive pattern formed on the electric insulation layer,
wherein the conductive pattern includes a terminal portion provided to reach a vicinity of an edge of the base layer such that a connector terminal can contact conductively with the terminal portion, and
a protection layer having electric insulation properties is provided at least on a portion of the electric insulation layer between an end portion of the terminal portion on a side of the edge and the edge of the base layer.

10. The card edge type printed wiring board according to claim 9, wherein the protection layer includes a portion that covers a portion of the terminal portion in a vicinity of the end portion.
